(19) United States
(12) Patent Application Publication
(10) Pub. No.: US 2012/0091485 A1
(43) Pub. Date: Apr. 19, 2012

(54) LIGHT EMITTING DEVICE

(75) Inventors: SHIUN-WEI CHAN, Hsinchu (TW); CHIH-HSUN KE, Hsinchu (TW)

(73) Assignee: ADVANCED OPTOELECTRONIC TECHNOLOGY, INC., Hsinchu Hsien (CN)

(21) Appl. No.: 13/169,030

(22) Filed: Jun. 27, 2011

(30) Foreign Application Priority Data
Oct. 14, 2010 (CN) 201010503799.8

(51) Int. Cl. H01L 33/58; H01L 33/42

(52) U.S. Cl. 257/91; 257/98; 257/88; 257/E33.061

(57) ABSTRACT

A light emitting diode device comprises a light source and a gas vent device. The gas vent device comprises a base having a collector, wherein a conversion element is located inside the collector. A portion of heat generated from the light source is transferred into thermal energy to gasify the conversion element and the other portion is dissipated via the gas vent device. Therefore, the light emitting device is able to provide illuminant and gasify the conversion element simultaneously.

1. Technical Field

The disclosure relates generally to light emitting devices, and more particularly to a light emitting device having multiple functions.

2. Description of the Related Art

Light emitting diodes (LEDs) are widely used in lighting due to their high efficiency and low power consumption. Generally, an operating LED produces luminous energy and thermal energy at the same time, wherein the thermal energy should be removed as timely as possible to prevent overheating of the LED device. Particularly, a high power LED device may comprise a thermal dissipation unit to conduct heat generated from the LED chip to the outside. However, it is wasteful to just dissipate the heat rather than apply to advantage.

### BRIEF DESCRIPTION OF THE DRAWINGS

FIG. 1 is a schematic view showing a light emitting device in accordance with one embodiment of the disclosure.

FIG. 2 is a cross section of the light emitting device in accordance with FIG. 1.

FIG. 3 is a schematic view showing a light emitting device in accordance with another embodiment of the disclosure.

### DETAILED DESCRIPTION

Reference will now be made to the drawings to describe the exemplary embodiments in detail.

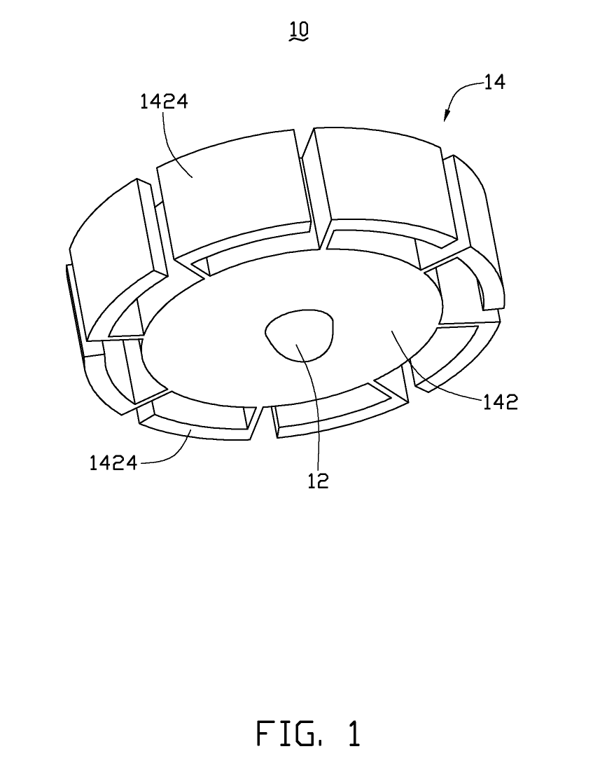

Referring to FIG. 1, the disclosure provides a light emitting device 10, comprising a light source 12 and a gas vent device 14. The light source 12 is located on a base 142 of the gas vent device 14. In the disclosure, the light source 12 is located on a bottom surface of the base 142, for providing illumination downward. Alternatively, the light source 12 can be located on a lateral surface or a top surface of the base 142 to provide lighting in different directions.

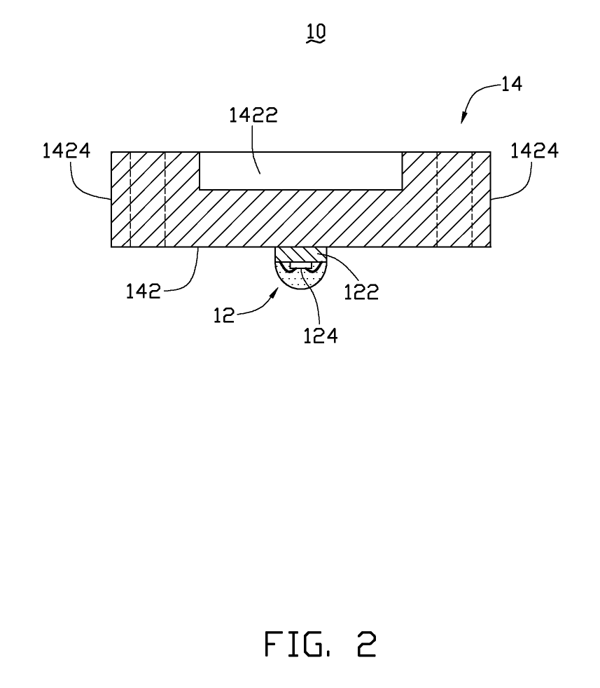

As shown in FIG. 2, the light source 12 comprises a substrate 122 and at least one LED chip 124 disposed on the substrate 122. The substrate 122 is contacted to the base 142, whereby heat generated from the at least one LED chip 124 is able to conduct to the base 142 through the substrate 122. Moreover, the substrate 122 has high thermal conductivity and high reflectivity so that thermal-dissipation efficiency and light emitting efficiency of the light source 12 is enhanced. For further increasing the thermal-dissipation efficiency and light emitting efficiency of the light source 12, the substrate 122 can be composed of silicon having a distributed Bragg reflector (DBR) located thereon.

The gas vent device 14 further comprises a collector 1422 for locating a conversion element (not shown) inside thereof. In the disclosure, the collector 1422 is a recess on a top surface of the base 142. The base 142 can be composed of metal, ceramic or other compounded material that is highly thermally-conductive. Conduction of heat by the base 142 and the substrate 122 from the at least one LED chip 124 can also heat the conversion element inside the collector 1422. The conversion element can be a volatile liquid or solid such as essential oils, incense, or mosquito repellent that readily evaporates when heated.

The base 142 further comprises a plurality of fins 1424 around the base 142, for increasing the thermal dissipation area and the thermal-dissipation efficiency of the base 142. In the disclosure, the base 142 comprises a lateral surface (not labeled) connected to the top surface and the bottom surface of the base 142, where the fins 1424 are located.

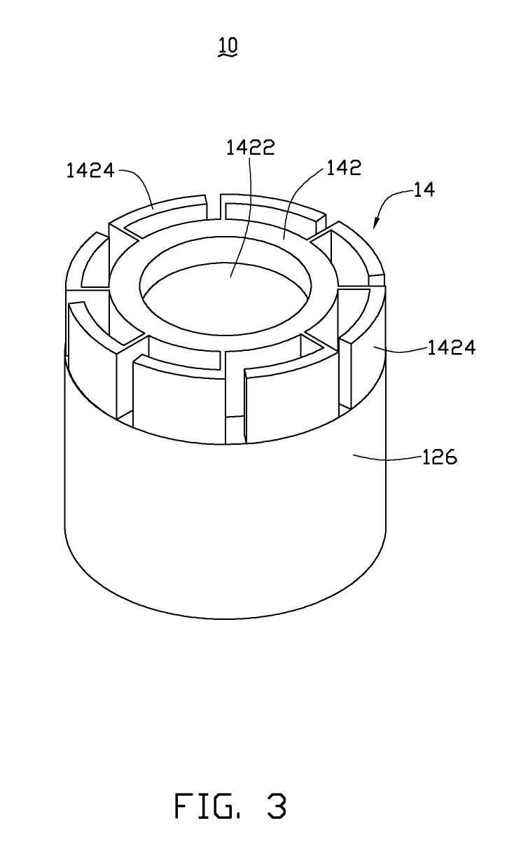

Referring to FIG. 3, the light emitting device 10 may include an optical lens 126 covering the light source 12, for modifying the light from the light source 12. The optical lens 126 can be any shape or type required for focusing, diffusing, coloring etc. as desired. In the disclosure, the optical lens 126 further comprises a luminescent conversion element (not shown), wherein the luminescent conversion element can be excited by light, and then, produce longer wavelength light to mix with the light emitted from the LED chip 124.

According to the disclosure, the light emitting device 10 simultaneously provides illumination and heat to vaporize the conversion element into the air via the gas vent device 14. Accordingly, the lifetime and the light efficiency of the light source 12 are enhanced, and a light emitting device 10 having multiple functions is provided.

It is to be understood, however, that even though multiple characteristics and advantages of the disclosure have been set forth in the foregoing description, together with details of the structure and function of the invention disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting device, comprising:
a light source, comprising a substrate and at least one LED (light emitting diode) chip disposed on the substrate; and
a gas vent device, comprising a heat-conductive base having a collector and a conversion element, wherein the conversion element is located inside the collector and the light source is located on the gas vent device, heat generated by the at least one LED chip in operation causing the conversion element to convert from its original state to a vapor state.

2. The light emitting device as claimed in claim 1, wherein the substrate of the light source contacts to the base.

3. The light emitting device as claimed in claim 2, wherein the light source is opposite to the collector.

4. The light emitting device as claimed in claim 2, wherein the substrate of the light source has high thermal conductivity and high reflectivity.

5. The light emitting device as claimed in claim 4, wherein the substrate of the light source is silicon having a distributed Bragg reflector (DBR) located thereon.

6. The light emitting device as claimed in claim 1, wherein the collector is a recess on the top of the base.

7. The light emitting device as claimed in claim 1, wherein the base is composed of metal, ceramic or compound material.

8. The light emitting device as claimed in claim 1, wherein a plurality of fins is defined around the base.

9. The light emitting device as claimed in claim 1, wherein the conversion element is a volatile liquid or solid.

10. The light emitting device as claimed in claim 1, wherein an optical lens is located upon the light source.

11. The light emitting device as claimed in claim 10, wherein the optical lens comprises a luminescent conversion element.

12. A light emitting device, comprising:
a heat-conductive base, having a top surface, a bottom surface located opposite to the top surface, and a lateral surface connected the top surface and the bottom surface, wherein a collector is located on the top surface;
a light source comprising at least one light emitting diode chip and disposed on the bottom surface; and
a conversion element, located inside the collector;
wherein heat generated by the at least one light emitting diode chip in operation is transferred to the conversion element in the collector via the base to cause the conversion element to convert from its original state to a vapor state.

13. The light emitting device as claimed in claim 12, wherein the conversion element is a volatile liquid or solid state.

14. The light emitting device as claimed in claim 12, wherein fins are located on the lateral surface.

15. The light emitting device as claimed in claim 12, wherein the light source comprises a substrate applying to the bottom surface and the at least one light emitting chip is located on the substrate.

16. The light emitting device as claimed in claim 15, wherein the light source further comprises an optical lens covering the at least one light emitting diode chip.

17. The light emitting device as claimed in claim 16, wherein the optical lens comprising a luminescent conversion element.
